(19) United States
(12) Patent Application Publication
(10) Pub. No.: US 2021/0359133 A1
(43) Pub. Date: Nov. 18, 2021

(54) OXIDE THIN-FILM TRANSISTOR DEVICE AND MANUFACTURING METHOD THEREOF

(71) Applicant: SHENZHEN CHINA STAR OPTOELECTRONICS SEMICONDUCTOR DISPLAY TECHNOLOGY CO., LTD., SHENZHEN (CN)

(72) Inventor: MING-JIUE YU, SHENZHEN (CN)

(21) Appl. No.: 16/620,028

(22) PCT Filed: May 23, 2019
(86) PCT No.: PCT/CN2019/088058

§ 371 Date: Dec. 6, 2019

(30) Foreign Application Priority Data
May 8, 2019 (CN) 201910381390.4

(51) Int. Cl. H01L 29/786; H01L 29/66

(52) U.S. Cl. CPC H01L 29/7869; H01L 29/66742; H01L 29/78696

(57) ABSTRACT

The present disclosure provides an oxide thin-film transistor device and manufacturing method thereof, the method of manufacturing the oxide thin-film transistor device including: depositing a buffer layer on a substrate; depositing a first channel layer composed of a wide bandgap oxide semiconductor on the buffer layer; depositing a second channel layer composed of a high-mobility oxide semiconductor on the first channel layer, which can improve electron mobility and reliability of device.

### FIELD OF INVENTION

The present disclosure relates to the field of display technologies, and more particularly to an oxide thin-film transistor device and a method of manufacturing an oxide thin-film transistor device.

### BACKGROUND OF INVENTION

To meet operational demands of current active-matrix organic light-emitting to diode (AMOLED) driving circuits, a driving thin-film transistor usually use a high electron mobility material as channel material; however, the high electron mobility material usually has more oxygen defects, which is easy to reduce device reliability.

Therefore, there is a need to provide an oxide thin-film transistor device and a method of manufacturing the oxide thin-film transistor device to solve issues in the prior art.

In current active-matrix organic light-emitting diode (AMOLED) driving circuits, the channel material with high electron mobility usually has more oxygen defects, therefore easy to reduce device reliability.

### SUMMARY OF INVENTION

To solve the above problems, the present disclosure provides an oxide thin-film transistor device and a method of manufacturing an oxide thin-film transistor device which can improve an electron mobility and a reliability of device.

To achieve the above objective, the present disclosure provides a method of manufacturing an oxide thin-film transistor device, including: depositing a buffer layer on a substrate; depositing a first channel layer composed of a wide bandgap oxide semiconductor on the buffer layer; depositing a second channel layer composed of a high-mobility oxide semiconductor on the first channel layer; depositing a gate insulator on the second channel layer; depositing a gate metal layer on the gate insulator to define a gate area of the oxide thin-film transistor device; depositing an interlayer dielectric on the buffer layer, the first channel layer, the second channel layer, the gate insulator, and the gate metal layer; forming a source channel and a drain channel connected to the second channel layer in the interlayer dielectric; and depositing a source metal layer and a drain metal layer on the interlayer dielectric to define a source area and a drain area of the oxide thin-film transistor device.

In an embodiment of the present disclosure, the buffer layer comprises SiO2.

In an embodiment of the present disclosure, further comprising baking the substrate before depositing the buffer layer on the substrate.

In an embodiment of the present disclosure, wherein the wide bandgap oxide semiconductor comprises Hf—In—Zn—O.

In an embodiment of the present disclosure, wherein the high-mobility oxide semiconductor comprises IGZO.

In an embodiment of the present disclosure, wherein the high-mobility oxide semiconductor comprises ITZO.

Wherein, the IGTO means an In—Ga—Sn—O based oxide semiconductor, ITZO means an In—Sn—Zn—O based oxide semiconductor.

In an embodiment of the present disclosure, wherein a thickness of the first channel layer is greater than a thickness of the second channel layer.

In an embodiment of the present disclosure, wherein a thickness of the first channel layer ranges between 30 nm and 50 nm.

In an embodiment of the present disclosure, wherein a thickness of the second channel layer ranges between 5 nm and 10 nm.

In an embodiment of the present disclosure, further comprising forming a self-aligned gate structure by downward etching the gate metal layer and the gate insulator, after depositing the gate metal layer.

To achieve the above objective, the present disclosure further provides an oxide thin-film transistor device, comprising: a substrate; a buffer layer disposed on the substrate; a first channel layer disposed on the buffer layer, wherein the first channel layer is composed of a wide bandgap oxide semiconductor; a second channel layer disposed on the first channel layer, wherein the second channel layer is composed of a high-mobility oxide semiconductor; a gate insulator disposed on the second channel layer; a gate metal layer disposed on the gate insulator to define a gate area of the oxide thin-film transistor device; an interlayer dielectric disposed on the buffer layer, the first channel layer, the second channel layer, the gate insulator, and the gate metal layer; a source channel and a drain channel disposed in the interlayer dielectric, wherein the source channel and the drain channel are connected to the second channel layer; and a source metal layer and a drain metal layer disposed on the interlayer dielectric, to define a source area and a drain area of the oxide thin-film transistor device.

In an embodiment of the present disclosure, wherein the buffer layer comprises SiO2.

In an embodiment of the present disclosure, wherein the substrate comprises glass and/or polyimide.

In an embodiment of the present disclosure, wherein the wide bandgap oxide semiconductor comprises Hf—In—Zn—O.

In an embodiment of the present disclosure, wherein the high-mobility oxide semiconductor comprises IGZO.

In an embodiment of the present disclosure, wherein the high-mobility oxide semiconductor comprises ITZO.

In an embodiment of the present disclosure, wherein a thickness of the first channel layer is greater than a thickness of the second channel layer.

In an embodiment of the present disclosure, wherein a thickness of the first channel layer ranges between 30 nm and 50 nm.

In an embodiment of the present disclosure, wherein a thickness of the second channel layer ranges between 5 nm and 10 nm.

In an embodiment of the present disclosure, wherein a gate metal channel is further disposed under the gate metal layer, and a gate dielectric channel is further disposed under the gate insulator to form a self-aligned gate structure.

Because of the oxide thin-film transistor device and manufacturing method thereof of the embodiments of the present disclosure, the method of manufacturing the oxide thin-film transistor device including: depositing a buffer layer on a substrate; depositing a first channel layer composed of a wide bandgap oxide semiconductor on the buffer layer; depositing a second channel layer composed of a high-mobility oxide semiconductor on the first channel layer, which can improve an electron mobility and a reliability of device, reduce lighting effects. Moreover, can reduce the using of the mask and the cost of manufacturing the oxide thin-film transistor device.

### DESCRIPTION OF DRAWINGS

FIG. 1 shows a flowchart of a method of manufacturing an oxide-thin film transistor device according an embodiment of the present disclosure.

FIG. 2 shows a structural schematic diagram of an oxide-thin film transistor device according an embodiment of the present disclosure.

FIG. 3 shows a structural schematic diagram of an oxide-thin film transistor device according an embodiment of the present disclosure.

### DETAILED DESCRIPTION OF PREFERRED EMBODIMENTS

In order to make the above description of the present disclosure and other objects, features, and advantages of the present disclosure more comprehensible, preferred embodiments are described below, and are described in detail below with reference to the accompanying drawings. Furthermore, directional terms described by the present disclosure, such as up, down, top, bottom, front, back, left, right, inner, outer, side, surrounding, center, horizontal, vertical, longitudinal, axial, radial, uppermost or lowermost, etc., are only directions by referring to the accompanying drawings, and thus the used terms are used only for the purpose of describing embodiments of the present disclosure and are not intended to be limiting of the present disclosure.

In the drawings, units with similar structures are labeled with the same reference number.

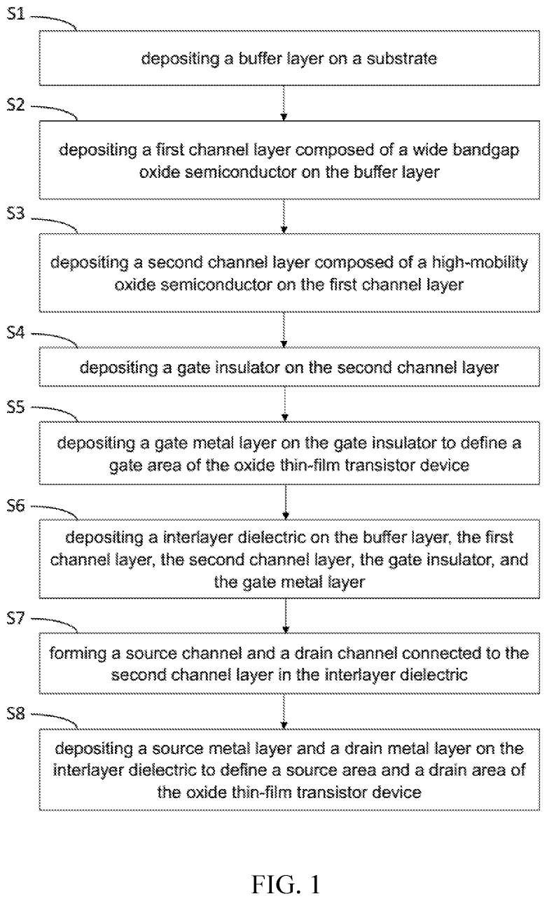

Please refer to FIG. 1, which shows a schematic flowchart of a method of manufacturing an oxide-thin film transistor device according an embodiment of the present disclosure, including:

Step S1: depositing a buffer layer on a substrate.

Wherein, in an embodiment of the present disclosure, the substrate includes glass and/or polyimide (PI).

Wherein, in an embodiment of the present disclosure, the buffer layer includes SiO2.

Wherein, in an embodiment of the present disclosure, before processing the step S1, the substrate can be pre-processed with a substrate processing method, to improve production yield of the oxide-thin film transistor device according the present disclosure. For example, the substrate processing method includes baking the substrate to make the deposited buffer layer material more easily attach to the substrate, further increasing utilization of the buffer layer material.

Step S2: depositing a first channel layer composed of a wide bandgap oxide semiconductor on the buffer layer.

Wherein, in an embodiment of the present disclosure, the wide band gap oxide semiconductor has an energy gap of about 3.5 electron volts, for example, wherein the wide bandgap oxide semiconductor includes an Hf—In—Zn—O based oxide semiconductor.

Step S3: depositing a second channel layer composed of a high-mobility oxide semiconductor on the first channel layer.

Wherein, in an embodiment of the present disclosure, the high-mobility oxide semiconductor includes at least one of IGZO and ITZO. Wherein the IGTO means an In—Ga—Sn—O based oxide semiconductor, ITZO means an In—Sn—Zn—O based oxide semiconductor.

More specifically, in the oxide thin-film transistor of the present disclosure, by making a thickness of the first channel layer greater than a thickness of the second channel layer, thereby improving the mobility and reliability of the oxide thin film transistor of the present disclosure.

Wherein, in an embodiment of the present disclosure, a thickness of the first channel layer ranges between 30 nm and 50 nm.

Wherein, in an embodiment of the present disclosure, a thickness of the second channel layer ranges between 5 nm and 10 nm.

Step S4: depositing a gate insulator (GI) on the second channel layer.

Wherein, in an embodiment of the present disclosure, the gate insulator includes single layer SiNx, single layer SiO2, or double layer film structure.

Step S5: depositing a gate metal layer on the gate insulator to define a gate area of the oxide thin-film transistor device.

Step S6: depositing an interlayer dielectric (ILD) on the buffer layer, the first channel layer, the second channel layer, the gate insulator, and the gate metal layer.

In an embodiment of the present disclosure, the interlayer dielectric includes single layer SiNx, single layer SiO2.

Step S7: forming a source channel and a drain channel connected to the second channel layer in the interlayer dielectric.

Step S8: depositing a source metal layer and a drain metal layer on the interlayer dielectric to define a source area and a drain area of the oxide thin-film transistor device.

Wherein, in an embodiment of the present disclosure, the gate metal layer, the source metal layer, and the drain metal layer include at least one of Mo, Al, and Cu.

Wherein, in an embodiment of the present disclosure, after depositing the gate metal layer, further forming a self-aligned gate structure by downward etching the gate metal layer and the gate insulator, thereby further reducing a parasitic capacitance between the gate and the source, and a parasitic capacitance between the gate and the drain.

In an embodiment of the present disclosure, after manufacturing the oxide thin-film transistor device of the present disclosure, by sequentially forming a protective layer, a planarization layer, an indium-tin oxide (ITO) electrode and a pixel defining layer, further manufacture a back-sheet including the oxide thin-film transistor device according to the present disclosure.

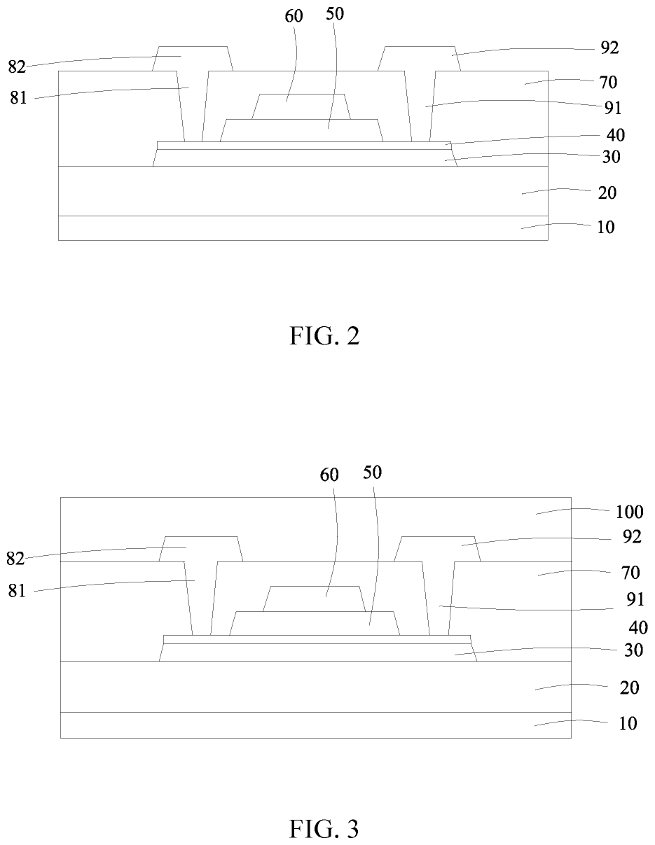

Please refer to FIG. 2, which shows a structural schematic diagram of an oxide-thin film transistor device according an embodiment of the present disclosure. In an embodiment, the oxide thin-film transistor device including a substrate 10, a buffer layer 20, a first channel layer 30, a second channel layer 40, a gate insulator 50, a gate metal layer 60, an interlayer dielectric 70, a source channel 81, a source metal layer 82, a drain channel 91 and a drain metal layer 92.

Wherein, the buffer layer 20 disposed on the substrate 10. The first channel layer 30 disposed on the buffer layer 20, wherein the first channel layer 30 is composed of to a wide bandgap oxide semiconductor. The second channel layer 40 disposed on the first channel layer 30, wherein the second channel layer 40 is composed of a high-mobility oxide semiconductor. The gate insulator 50 disposed on the second channel layer 40. The gate metal layer 60 disposed on the gate insulator 50 to define a gate area of the oxide thin-film transistor device. The interlayer dielectric 50 disposed on the buffer layer 20, the first channel layer 30, the second channel layer 40, the gate insulator 50, and the gate metal layer 60. The source channel 81 and the drain channel 91 disposed in the interlayer dielectric 70, wherein the source channel 81 and the drain channel 91 are connected to the second channel layer 40. The source metal layer 82 and the drain metal layer 92 disposed on the interlayer dielectric 70, to define the source area and the drain area of the oxide thin-film transistor device.

Wherein, in an embodiment of the present disclosure, the substrate includes glass and/or polyimide (PI).

Wherein, in an embodiment of the present disclosure, the buffer layer 20 includes SiO2.

Wherein, in an embodiment of the present disclosure, the substrate 10 can be pre-processed with a substrate processing method, to improve production yield of the oxide-thin film transistor device according the present disclosure. For example, the substrate 10 processing method includes baking the substrate 10 to make the deposited buffer layer material more easily attached to the substrate, further increasing the utilization of the buffer layer material.

Wherein, in an embodiment of the present disclosure, the wide band gap oxide semiconductor has an energy gap of about 3.5 electron volts, for example, wherein the wide bandgap oxide semiconductor includes an Hf—In—Zn—O based oxide semiconductor.

Wherein, in an embodiment of the present disclosure, the high-mobility oxide semiconductor includes at least one of IGZO and ITZO. Wherein the IGTO means an In—Ga—Sn—O based oxide semiconductor, ITZO means an In—Sn—Zn—O based oxide semiconductor.

More specifically, in the oxide thin-film transistor of the present disclosure, by making a thickness of the first channel layer 30 greater than a thickness of the second channel layer 40, thereby improving the mobility and reliability of the oxide thin film to transistor of the present disclosure.

Wherein, in an embodiment of the present disclosure, a thickness of the first channel layer 30 ranges between 30 nm and 50 nm.

Wherein, in an embodiment of the present disclosure, a thickness of the second channel layer 40 ranges between 5 nm and 10 nm.

Wherein, in an embodiment of the present disclosure, the gate insulator 50 includes single layer SiNx, single layer SiO2, or double layer film structure.

Wherein, in an embodiment of the present disclosure, the gate metal layer 60, the source metal layer 82, and the drain metal layer 92 include at least one of Mo, Al, and Cu.

Wherein, in an embodiment of the present disclosure, a gate metal channel is further disposed under the gate metal layer, and a gate dielectric channel is further disposed under the gate insulator to form a self-aligned gate structure. Thereby further reduce a parasitic capacitance between the gate and the source, and a parasitic capacitance between the gate and the drain.

Please refer to FIG. 3, which shows a structural schematic diagram of an oxide-thin film transistor device according an embodiment of the present disclosure. It different from the embodiment disclosed in FIG. 2 in that further includes a protective layer 100 disposed on the interlayer dielectric 70, the source metal layer 82, and the drain metal layer 92, by disposing the protective layer 100, improving a stability of oxide thin film transistor device.

In an embodiment of the present disclosure, the protective layer 100 includes polyvinylchloride (PVC).

Furthermore, after manufacturing the oxide thin-film transistor device of the present disclosure, by sequentially forming a protective layer, a planarization layer, an indium-tin oxide (ITO) electrode and a pixel defining layer, further manufacture a back-sheet including the oxide thin-film transistor device according to the present disclosure.

In summary, because of the oxide thin-film transistor device and manufacturing method thereof of the embodiments of the present disclosure, the method of manufacturing the oxide thin-film transistor device including: depositing a buffer layer on a substrate; depositing a first channel layer composed of a wide bandgap oxide semiconductor on the buffer layer; depositing a second channel layer composed of a high-mobility oxide semiconductor on the first channel layer, which can improve an electron mobility and a reliability of device, reduce lighting effects. Moreover, can reduce the using of the mask and the cost of manufacturing the oxide thin-film transistor device.

Although the present disclosure is described via one or more embodiments, those of ordinary skill in the art can come up with equivalent variations and modifications based upon the understanding of the specification and the accompanying drawings. The present disclosure includes all such modifications and variations, and is only limited by the scope of the appended claims. In particular, as to the various functions performed by the components described above, the terms used to describe the components are intended to correspond to any component performing the specific functions (e.g., which are functionally equivalent) of the components (unless otherwise indicated), even those which are structurally different from the disclosed structure for performing the functions in the exemplary embodiments in the specification shown herein. In addition, although a particular feature in the specification is disclosed in only one of many embodiments, this feature may be combined with one or more features in other embodiments which are desirable and advantageous to a given or particular application. Moreover, the terms “include”, “have”, “consist of”, or variations thereof used in the detailed description or the claims are intended to be used in a manner similar to the term “comprising”.

The above are only preferred embodiments of the present disclosure, and it should be noted that those skilled in the art can also make several improvements and refinements without departing from the principles of the present disclosure. These improvements and refinements should also be considered in a protected range of the present disclosure.

In summary, although the preferable embodiments of the present disclosure have been disclosed above. It should be noted that those of ordinary skill in the art can make a variety of improvements and substitutions on the premise of not deviating from the technical principle of the present disclosure, and these improvements and substitutions should be encompassed within the protection scope of the present disclosure.

What is claimed is:

1. A method of manufacturing an oxide thin-film transistor device, comprising:
depositing a buffer layer on a substrate;
depositing a first channel layer composed of a wide bandgap oxide semiconductor on the buffer layer;
depositing a second channel layer composed of a high-mobility oxide semiconductor on the first channel layer;
depositing a gate insulator on the second channel layer;
depositing a gate metal layer on the gate insulator to define a gate area of the oxide to thin-film transistor device;
depositing an interlayer dielectric on the buffer layer, the first channel layer, the second channel layer, the gate insulator, and the gate metal layer;
forming a source channel and a drain channel connected to the second channel layer in the interlayer dielectric; and
depositing a source metal layer and a drain metal layer on the interlayer dielectric to define a source area and a drain area of the oxide thin-film transistor device.

2. The method of manufacturing the oxide thin-film transistor device according to claim 1, wherein the buffer layer comprises SiO2.

3. The method of manufacturing the oxide thin-film transistor device according to claim 1, further comprising baking the substrate before depositing the buffer layer on the substrate.

4. The method of manufacturing the oxide thin-film transistor device according to claim 1, wherein the wide bandgap oxide semiconductor comprises Hf—In—Zn—O.

5. The method of manufacturing the oxide thin-film transistor device according to claim 1, wherein the high-mobility oxide semiconductor comprises IGZO.

6. The method of manufacturing the oxide thin-film transistor device according to claim 1, wherein the high-mobility oxide semiconductor comprises ITZO.

7. The method of manufacturing the oxide thin-film transistor device according to claim 1, wherein a thickness of the first channel layer is greater than a thickness of the second channel layer.

8. The method of manufacturing the oxide thin-film transistor device according to claim 1, wherein a thickness of the first channel layer ranges between 30 nm and 50 nm.

9. The method of manufacturing the oxide thin-film transistor device according to claim 1, wherein a thickness of the second channel layer ranges between 5 nm and 10 nm.

10. The method of manufacturing the oxide thin-film transistor device according to claim 1, further comprising forming a self-aligned gate structure by downward etching the gate metal layer and the gate insulator, after depositing the gate metal layer.

11. An oxide thin-film transistor device, comprising:
a substrate;
a buffer layer disposed on the substrate;
a first channel layer disposed on the buffer layer, wherein the first channel layer is composed of a wide bandgap oxide semiconductor;
a second channel layer disposed on the first channel layer, wherein the second channel layer is composed of a high-mobility oxide semiconductor;
a gate insulator disposed on the second channel layer;
a gate metal layer disposed on the gate insulator to define a gate area of the oxide thin-film transistor device;
an interlayer dielectric disposed on the buffer layer, the first channel layer, the second channel layer, the gate insulator, and the gate metal layer;
a source channel and a drain channel disposed in the interlayer dielectric, wherein the source channel and the drain channel are connected to the second channel layer; and
a source metal layer and a drain metal layer disposed on the interlayer dielectric, to define a source area and a drain area of the oxide thin-film transistor device.

12. The oxide thin-film transistor device according to claim 11, wherein the buffer layer comprises SiO2.

13. The oxide thin-film transistor device according to claim 11, wherein the substrate comprises glass and/or polyimide.

14. The oxide thin-film transistor device according to claim 11, wherein the wide bandgap oxide semiconductor comprises Hf—In—Zn—O.

15. The oxide thin-film transistor device according to claim 11, wherein the high-mobility oxide semiconductor comprises IGZO.

16. The oxide thin-film transistor device according to claim 11, wherein the high-mobility oxide semiconductor comprises ITZO.

17. The oxide thin-film transistor device according to claim 11, wherein a thickness of the first channel layer is greater than a thickness of the second channel layer.

18. The oxide thin-film transistor device according to claim 11, wherein a thickness of the first channel layer ranges between 30 nm and 50 nm.

19. The oxide thin-film transistor device according to claim 11, wherein a thickness of the second channel layer ranges between 5 nm and nm.

20. The oxide thin-film transistor device according to claim 11, wherein a gate metal channel is further disposed under the gate metal layer, and a gate dielectric channel is further disposed under the gate insulator to form a self-aligned gate structure.
